(19) United States
(12) Patent Application Publication
(10) Pub. No.: US 2016/0351661 A1
(43) Pub. Date: Dec. 1, 2016

(54) PROCESS FOR PRODUCING MOS TRANSISTORS HAVING A LARGER CHANNEL WIDTH FROM AN SOI AND IN PARTICULAR FDSOI SUBSTRATE, AND CORRESPONDING INTEGRATED CIRCUIT

(71) Applicant: STMicroelectronics (Crolles 2) SAS, Crolles (FR)

(72) Inventors: Stephane Monfray, Eybens (FR); Thomas Skotnicki, Crolles-Montfort (FR)

(73) Assignee: STMicroelectronics (Crolles 2) SAS, Crolles (FR)

(21) Appl. No.: 14/962,193

(22) Filed: Dec. 8, 2015

(30) Foreign Application Priority Data
May 27, 2015 (FR) 1554755

(51) Int. Cl. H01L 29/06; H01L 29/78; H01L 21/02; H01L 29/66; H01L 29/165; H01L 29/423; H01L 21/762

(52) U.S. Cl. CPC H01L 29/0649; H01L 29/0692; H01L 29/42376; H01L 29/78; H01L 21/76264; H01L 29/66568; H01L 29/165; H01L 21/02532

(57) ABSTRACT

An integrated circuit includes a substrate with an isolation region that bounds a zone. A transistor includes a concave semiconductor region that is supported by the isolation region in a first direction and has a concavity turned to face towards the zone. The concave semiconductor region contains drain, source and channel regions. A gate region for the transistor possesses a concave portion overlapping a portion of the concave semiconductor region. A dielectric region is located between the zone of the substrate and the concave semiconductor region.

### PRIORITY CLAIM

This application claims priority from French Application for Patent No. 1554755 filed May 27, 2015, the disclosure of which is incorporated by reference.

### TECHNICAL FIELD

Methods of implementation and embodiments relate to integrated circuits, and more particularly to the fabrication of transistors comprising thin concave semiconductor films, from a silicon-on-insulator (SOI) substrate and more particularly from a fully depleted silicon-on-insulator (FDSOI) substrate.

### BACKGROUND

In general, a silicon-on-insulator substrate comprises a flat semiconductor film, for example made of silicon or a silicon alloy, of uniform thickness, resting on a buried insulating layer, commonly designated a “BOX” (for “buried oxide”), itself located on a carrier substrate, for example a semiconductor well.

Most particularly in an FDSOI technology, the semiconductor film possesses a very small thickness, for example of a few nanometers, and this thin film is fully depleted, thereby ensuring effective electrostatic control. The buried insulating layer is furthermore generally thin, for example about twenty nanometers in thickness. This type of substrate is advantageously designated an ultra-thin body and BOX fully depleted silicon-on-insulator (UTBB-FDSOI) substrate.

In general, by virtue of the intrinsic properties of FDSOI technology, such as low leakage current and effective control of “short channel” effects, the gate length of the transistors may be greatly decreased, thereby allowing more advanced technologies, for example 22 nm and lower technologies, to be used and the logic density of the integrated circuits to be increased.

However, despite all these advantageous features, the on-state current of transistors in an FDSOI CMOS technology is, for a given footprint on silicon, generally smaller than that of FinFET transistors because the latter, in general, comprise a larger effective channel width because of their three-dimensional structure.

### SUMMARY

Thus, according to one method of implementation and embodiment, it is proposed to increase, for a given footprint, the effective width of the channel and the on-state current of a transistor produced in an advanced CMOS SOI technology, such as an FDSOI technology, for example.

According to one aspect, an integrated circuit is provided including a substrate, an isolation region bounding at least one zone of the substrate, and at least one transistor.

The transistor comprises: a concave semiconductor region supported by the isolation region in a first direction, for example in the drain-source direction (along the length of the channel), having its concavity turned towards said at least one substrate zone and containing drain, source and channel regions; a gate region possessing a concave portion overlapping a portion of the concave semiconductor region; and a dielectric region located between said substrate zone and said concave semiconductor region.

Thus, the combination of a concave semiconductor region overlapped by a concave portion of the gate region makes it possible to obtain a channel that is concave, and that therefore has a larger width relative to a conventional flat-channel transistor, for a given footprint on the substrate.

The gate region overlaps a portion of the concave semiconductor region in the first direction (drain-source direction) so as to allow source and drain regions to be produced in said concave semiconductor region.

In a second direction, orthogonal to the first direction, the gate region may overlap a portion of the concave semiconductor region or indeed, preferably, the entirety of this concave semiconductor region so as to obtain a higher current gain.

According to one embodiment, the concave semiconductor region is located at a distance from said isolation region in the second direction.

Thus, the height of the portion of said isolation region extending in the second direction may be smaller than the height of the portion of said isolation region extending in the first direction.

According to one possible variant, the substrate may be a carrier substrate of an SOI substrate comprising a buried insulating layer supported by said carrier substrate, and said dielectric region includes at least one portion of said buried insulating layer and at least one other dielectric material between said portion of the buried insulating layer and said concave semiconductor region.

According to another possible variant, said dielectric region may comprise at least one first dielectric layer covering at least one zone of the substrate and at least one second dielectric layer lining the portion of the concave semiconductor region located facing said zone, and the transistor furthermore includes a metal region located between the two dielectric layers.

Such a variant allows more effective back biasing to be achieved.

According to another aspect, a process for fabricating a transistor is provided, comprising: forming a sacrificial region resting on an insulating layer, itself resting on a zone of a substrate, which zone is bounded by an isolation region, and protruding relative to this isolation region; growing by epitaxy a concave semiconductor region on said sacrificial region, said concave semiconductor region resting on the isolation region in a first direction; partially removing the portion of the isolation region extending in a second direction orthogonal to the first direction and removing at least partially said buried insulating layer so as to create an access to said sacrificial region; removing said sacrificial region so as to obtain a concave semiconductor region supported by the isolation region in the first direction and having its concavity turned towards said substrate zone; forming a dielectric region located between said substrate zone and said concave semiconductor region; and forming a gate region possessing a concave portion overlapping a portion of the concave semiconductor region in the first direction, said concave semiconductor region containing drain, source and channel regions.

According to one method of implementation, the gate region is formed so as to overlap a portion of the concave semiconductor region in the first direction and to overlap a portion or preferably the entirety of the concave semiconductor region in the second direction.

According to one method of implementation, the insulating layer and the substrate zone may belong to an SOI substrate comprising an initial semiconductor film and the formation of the sacrificial region includes forming, from said initial semiconductor film, a final semiconductor film that protrudes relative to said isolation region, the material of the final semiconductor film being selectively etchable relative to the material of the concave semiconductor region.

The material of the final semiconductor film may include a silicon-germanium alloy and said concave semiconductor region may include silicon.

According to one variant, the formation of said dielectric region may include partially removing said insulating layer and forming a dielectric zone between the remaining portion of said insulating layer and the concave semiconductor region.

According to another variant, the formation of said dielectric region may include: completely removing said insulating layer so as to expose said substrate zone; forming at least one first dielectric layer covering said zone of the substrate and forming at least one second dielectric layer lining the portion of the concave semiconductor region located facing said zone; and the process furthermore comprises forming a metal region (RM) located between the two dielectric layers (CD1, CD2).

### BRIEF DESCRIPTION OF THE DRAWINGS

Other advantages and features of the invention will become apparent on examining the detailed description of completely non-limiting methods of implementation and embodiments thereof and the appended drawings, in which:

FIGS. 1 to 16 schematically illustrate methods of implementation and embodiments.

### DETAILED DESCRIPTION

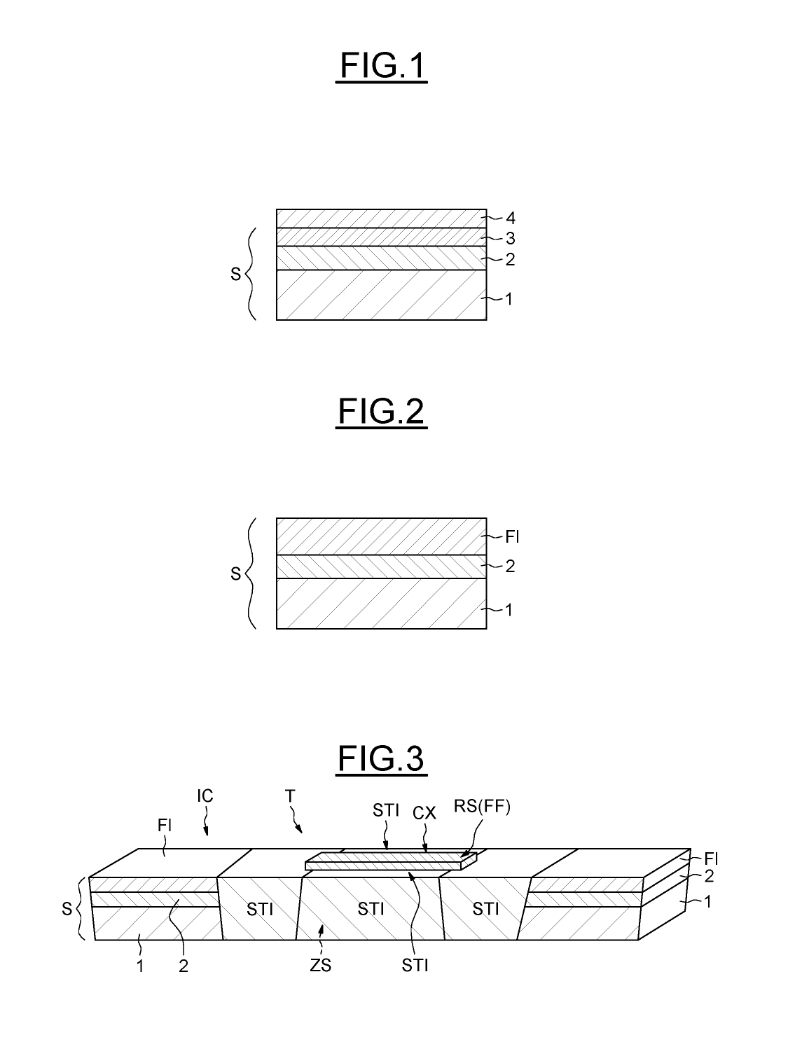

FIG. 1 illustrates a fully depleted silicon-on-insulator (FDSOI) substrate S including an initial semiconductor film 3, for example made of silicon and about 7 nm in thickness, on a buried insulating (BOX) layer 2 itself resting on a carrier substrate 1.

First, a silicon-germanium (SiGe) layer 4 that is for example 7 nm thick is formed by epitaxy on all the semiconductor film 3.

Next, a conventional step of condensation is carried out to produce a uniform intermediate semiconductor film FI made of silicon-germanium, as illustrated in FIG. 2.

After optionally forming localized orifices opening into the substrate 1, so as to be able to subsequently bias the substrate, followed by a conventional epitaxial regrowth, an isolation region STI is formed in a conventional way known per se (FIG. 3).

The isolation region STI bounds at least one substrate zone ZS dedicated to producing a transistor T and, for example, comprises shallow trench isolations (STIs) that isolate the substrate zone ZS from other components of the integrated circuit IC.

On the intermediate semiconductor film FI located on the buried insulating layer 2, conventional epitaxial growth of silicon-germanium is first carried out (FIG. 3). The thickness of this epitaxial layer CX is about 40 nm for example. As will be seen in more detail below, the thickness and geometry of this epitaxial layer CX will define the final shape of the concave channel of the transistor T.

It should be noted that this epitaxial layer CX extends partially over the isolation region STI whatever the orientation of the initial semiconductor film 3. It is however preferable for this film 3 to have a (110) orientation, so as to obtain vertical epitaxial facets.

The intermediate semiconductor film FI and the epitaxial layer CX de facto form a final semiconductor film FF that protrudes relative to the isolation region STI. As will be seen in more detail below, this film FF is in fact a sacrificial region RS.

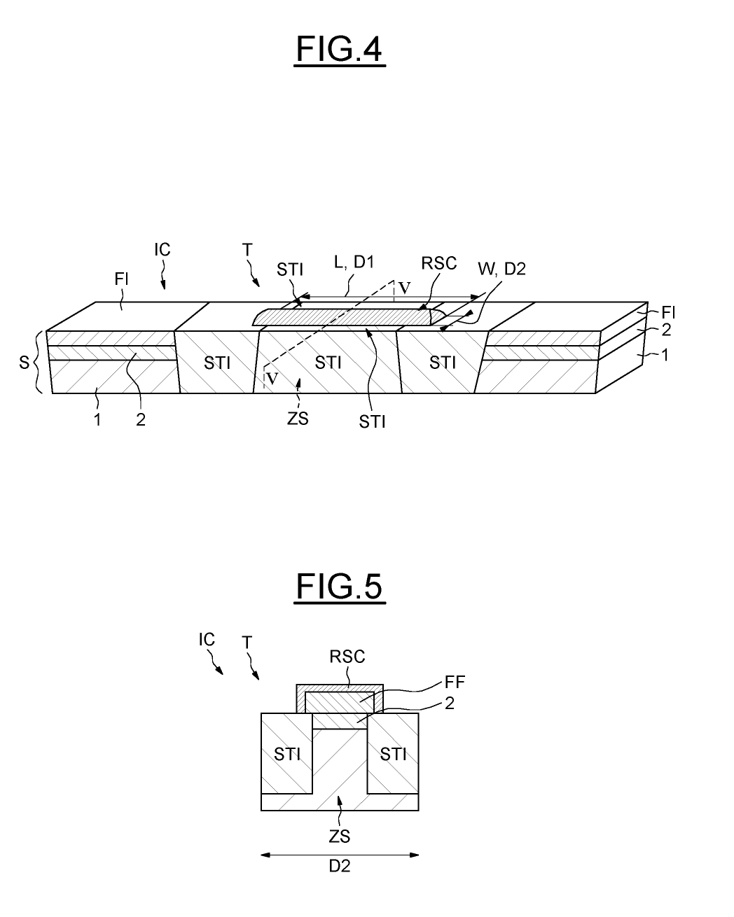

Next (FIG. 4), on the sacrificial region RS, a concave semiconductor region RSC, for example made of silicon, which covers the sacrificial region RS, is grown by epitaxy. The thickness of this concave semiconductor region RSC is about 10 nm, for example.

The first direction D1 is a direction along the length L of the channel of the future transistor and the second direction D2 is a direction along the width W of the channel, as illustrated in FIG. 4. Of course, the first direction D1 is orthogonal to the second direction D2.

Reference is now made to FIG. 5, which is a cross-sectional view along the line V-V in FIG. 4. It may clearly be seen that the final semiconductor film FF (sacrificial region) rests on the buried insulating layer 2 and partially extends over the isolation region STI in the second direction D2. The final semiconductor film FF is furthermore covered by the concave semiconductor region RSC made of silicon that also rests on the isolation region STI.

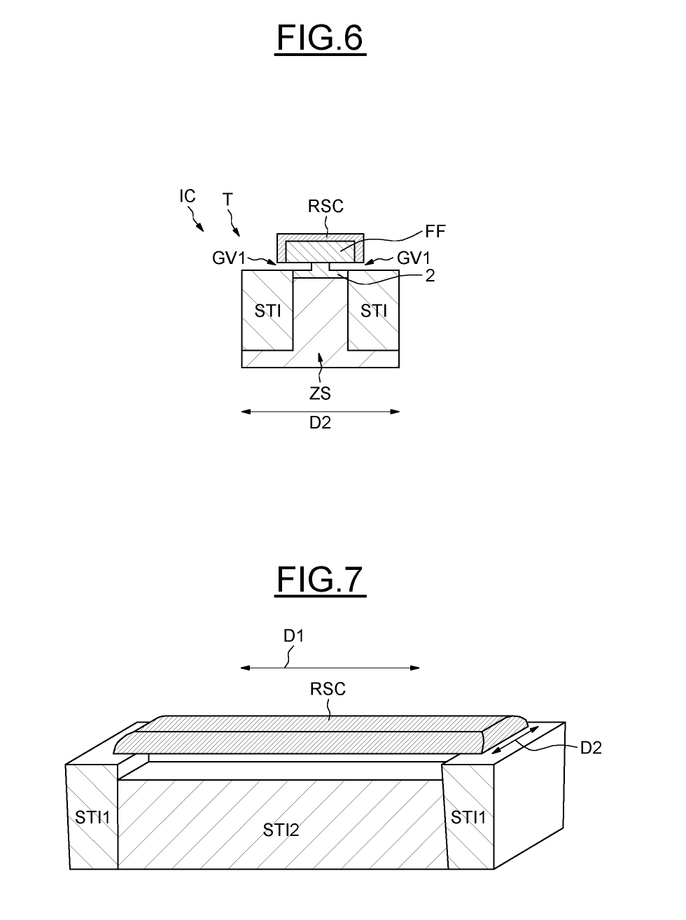

As illustrated in FIG. 6, next an anisotropic etch GV1 is carried out to partially remove a portion of the isolation region STI in the second direction D2 and to at least partially remove said buried insulating layer 2 so as to create an access to the sacrificial region RS.

As illustrated in FIG. 7, the structure of the sacrificial region RS and of the concave semiconductor region RSC is maintained stable by virtue of the portions of the region RSC resting on the isolation region STI in the first direction D1. It may also be seen that the height of the portion STI2 of the isolation region STI extending in the second direction D2 is smaller than the height of the portion STI1 of the isolation region STI extending in the first direction D1. This is because, during the etch GV1, the portion STI1 was protected.

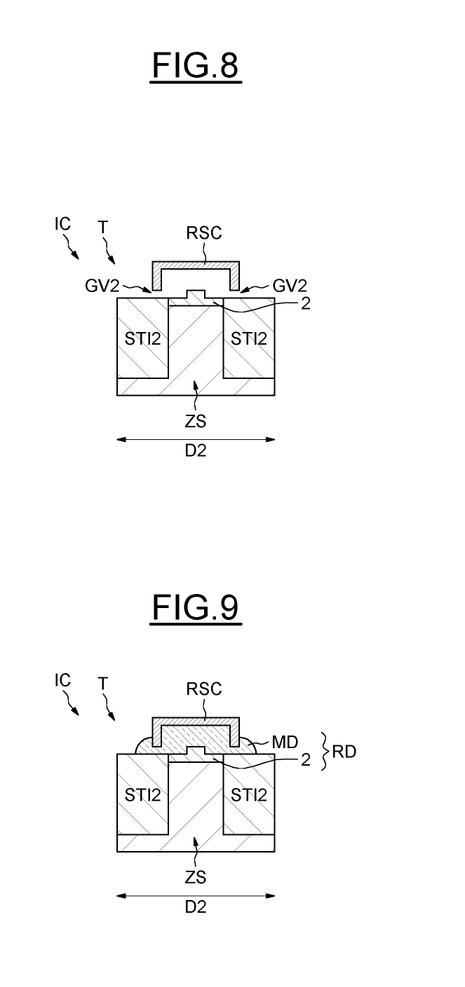

It should be noted that the final semiconductor film FF is selectively etchable relative to the material of the semiconductor region RSC. Using a selective etch GV2, the sacrificial region RS located between the concave semiconductor region RSC and the substrate zone ZS is removed. The concave semiconductor region RSC is then supported by the isolation region STI1 in the first direction D1 and has its concavity turned towards the substrate zone ZS, as may be seen in FIG. 8.

By way of indication, when the region RS includes silicon-germanium SiGe and the region RSC includes silicon, it is possible to use for the etch GV2 the following etch chemistries: NF₃+N₂, CF₄+N₂ or SF₆+N₂.

Next, a dielectric material MD, for example a silicon oxide/silicon nitride/silicon oxide (ONO) multilayer or an “HK—N—HK” multilayer of a high dielectric constant material (HK material), of a silicon nitride and of an HK material, is deposited between the remainder of the buried insulating layer and the concave semiconductor region RSC so as to fill the concavity of the concave semiconductor region RSC. After wet etching to remove the remainder of the material MD, the structure illustrated in FIG. 9 is obtained comprising a dielectric region RD between the concave region RSC and the substrate zone ZS.

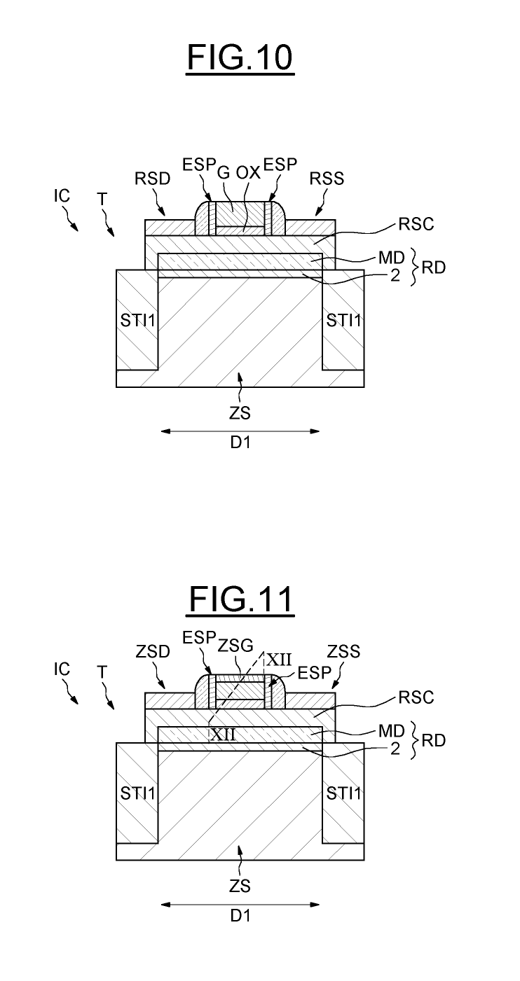

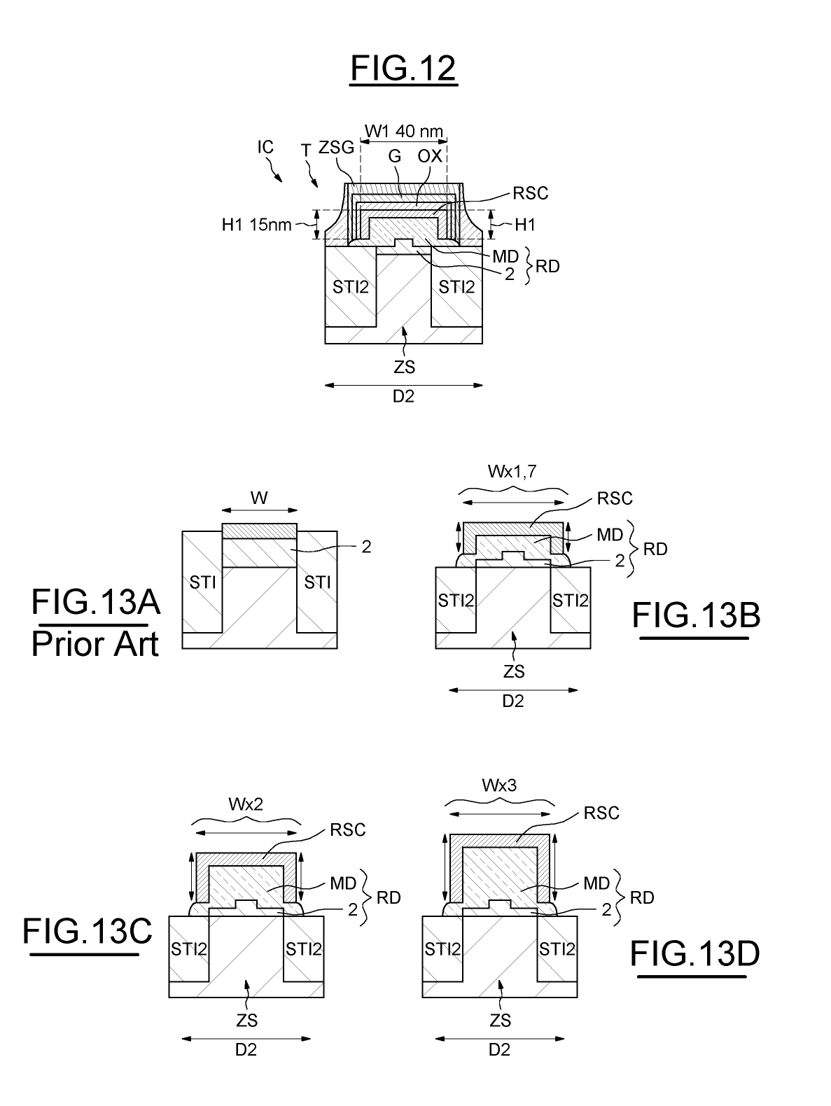

Reference is now made to FIG. 10, which shows a cross-sectional view X-X along the first direction D1 and to FIG. 12 which is a cross-sectional view along the line XII-XII (direction D2) in FIG. 11.

FIG. 10 shows that the concave semiconductor region RSC is supported by the isolation region STI1 in the first direction D1 with the dielectric region RD located between the concave semiconductor region RSC and the buried insulating layer 2.

Using a conventional “gate first” process, first a gate region G is formed overlapping a portion of the concave semiconductor region RSC and insulated from the concave semiconductor region RSC by a gate dielectric layer OX. Next, lateral insulating regions ESP (spacers) are formed about the insulated gate region G.

Next, by epitaxy, raised drain RSD and source RSS regions are formed.

Siliciding is then carried out in a conventional way known per se by depositing a metal layer, for example a nickel-platinum alloy, on the gate G, drain RSD and source RSS regions and then by applying a thermal anneal to form a metal silicide, for example NiSi.

Silicided zones ZSG, ZSD and ZSS are thus obtained (FIG. 11) on the gate G, drain RSD and source RSS regions.

As illustrated in FIG. 12, the effective width W of the channel of the transistor T becomes the sum of the width W1 of the concave semiconductor region, for example 40 nm, and two times its height H1, for example 15 nm, i.e. 70 nm in the present case.

It will be noted that in this embodiment, the gate region insulated by the gate oxide OX overlaps in the second direction D2 the concave region RSC in its entirety, thereby making it possible to obtain a concave gate region providing a higher current gain than would be the case if the concave gate region only overlapped in this second direction D2 a portion of the region RSC.

Moreover, in FIG. 12, the silicided region RSG also advantageously covers in the second direction D2 the gate region in its entirety.

By modifying the thickness of the sacrificial region RS and the corresponding shape of the concave semiconductor region RSC, it is advantageously possible, as illustrated in FIGS. 13B-13D, to further increase the effective width W of the channel of the transistor T relative to a prior-art transistor having a planar channel of width W and illustrated in FIG. 13A, or in other words to increase the on-state current of the transistor T, for a given footprint on the substrate.

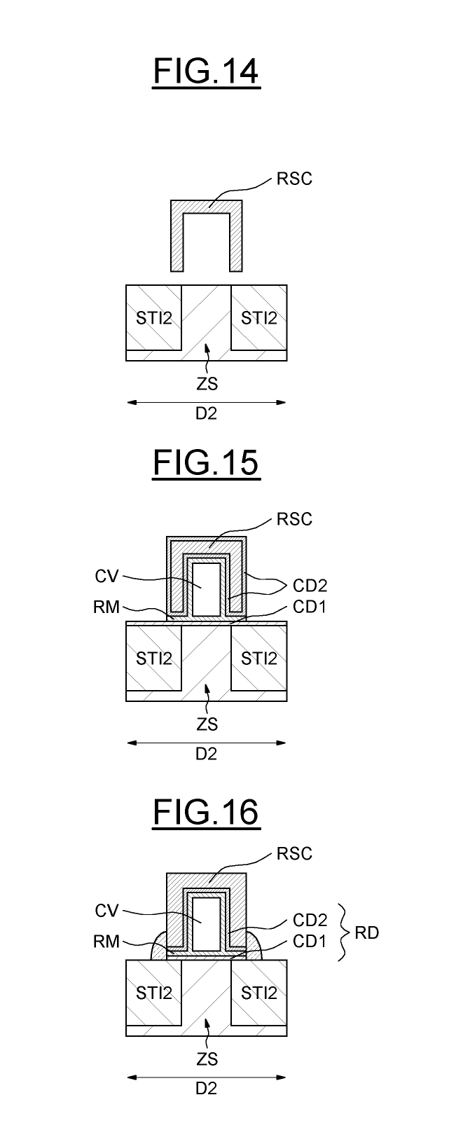

In one possible variant in FIGS. 14 to 16, it is possible to completely remove the buried insulating layer 2 so as to expose the carrier substrate 1, and to partially remove the portion STI2 of the isolation region STI extending in a second direction D2 after the concave semiconductor region RSC has been formed on the sacrificial region RS. Then, after the sacrificial region RS has been removed, the structure illustrated in FIG. 14 is obtained. Of course, the concave semiconductor region RSC is supported by the isolation region STI1 in the first direction D1.

Next, at least one first dielectric layer CD1 is formed covering the zone ZS of the substrate.

Furthermore, at least one second dielectric layer CD2 is formed that lines the portion of the concave semiconductor region RSC located facing the substrate zone ZS.

By way of indication, the first and second dielectric layers CD1 and CD2 may include a material having a high dielectric constant K, with a thickness of about a few nanometers. These two layers may be formed simultaneously.

Moreover, the process comprises forming, for example by deposition, a metal region RM that is located between the two dielectric layers CD1 and CD2, as illustrated in FIG. 15. Depending on the aspect ratio of the concave region RSC, a void CV may form in the metal region RM. But this is not of importance as the metal region remains present between the layers CD1 and CD2.

By selective etching, the portions of the dielectric layers CD1 and CD2 covering the concave semiconductor region RSC and partially the isolation region STI are removed.

These two layers CD1 and CD2 then form a dielectric region RD.

With the structure illustrated in FIG. 16, the transistor may advantageously benefit from more effective back biasing because of the presence of the metal region RM, which transfers the bias of the substrate right to the channel region RSC.

The invention is not limited to the methods of implementation and embodiments just described, but encompasses any variant thereof.

Thus it would be possible to use silicon as the sacrificial material and silicon-germanium for the channel region RSC for example by employing CF₄ and O₂ based etching processes that selectively etch silicon over SiGe.

1. An integrated circuit, comprising:
a substrate,
an isolation region bounding at least one zone of the substrate, and
at least one transistor comprising:
a concave semiconductor region supported by the isolation region in a first direction, said concave semiconductor region having a concavity turned towards said at least one zone and containing drain, source and channel regions,
a gate region possessing a concave portion overlapping a portion of the concave semiconductor region, and
a dielectric region located between said substrate zone and said concave semiconductor region.

2. The integrated circuit according to claim 1, wherein the gate region overlaps a portion of the concave semiconductor region in the first direction and overlaps at least a portion of the concave semiconductor region in a second direction orthogonal to the first direction.

3. The integrated circuit according to claim 1, wherein said concave semiconductor region is separated by a distance from said isolation region in the second direction.

4. The integrated circuit according to claim 1, wherein a height of a portion of said isolation region extending in the second direction is smaller than a height of a portion of said isolation region extending in the first direction.

5. The integrated circuit according to claim 1, wherein the substrate is a carrier substrate of an SOI substrate comprising a buried insulating layer supported by said carrier substrate, and wherein said dielectric region includes at least one portion of said buried insulating layer and at least one other dielectric material between said portion of the buried insulating layer and said concave semiconductor region.

6. The integrated circuit according to claim 1, wherein said dielectric region comprises at least one first dielectric layer covering said at least one zone of the substrate and at least one second dielectric layer lining the portion of the concave semiconductor region located facing said zone, and wherein the transistor further includes a metal region located between the first and second dielectric layers.

7-12. (canceled)

13. An integrated circuit, comprising:
a supporting substrate;
a region of insulating material supported by the supporting substrate and having a top surface and side edge surfaces;
a layer of semiconductor material that extends on the top surface and side edge surfaces of the region of insulating material to define a concave semiconductor region having a concavity facing towards said supporting substrate;
an oxide layer on said layer of semiconductor material; and
a gate electrode layer on said oxide layer and extending over a channel of the concave semiconductor region, said concave semiconductor region further including a source and drain on opposite sides of the channel.

14. An integrated circuit transistor, comprising:
a zone of a substrate bounded in a first direction at first and second ends by an isolation region;
a concave epitaxial semiconductor region extending along said first direction and in contact with the isolation region at said first and second ends and further extending over said zone, said concave epitaxial semiconductor region having a concavity facing towards said zone, said concavity separating the concave epitaxial semiconductor region from said zone;
a dielectric material located in said concavity between said zone and said concave epitaxial semiconductor region; and
a gate region possessing a concave portion overlapping a portion of the concave epitaxial semiconductor region,
wherein said concave epitaxial semiconductor region includes a drain region, a source region and a channel region.

15. The integrated circuit transistor of claim 14, wherein said zone of the substrate is bounded in a second direction perpendicular to the first direction by the isolation region, but wherein first and second sides of said concave epitaxial semiconductor region extending between the first and second ends are not in contact with the isolation region.

16. The integrated circuit transistor of claim 14, wherein forming the gate region comprises overlapping the gate region on a portion of the concave semiconductor region in the first direction and on at least a portion of the concave semiconductor region in the second direction.
